(19) United States
(12) Patent Application Publication
(10) Pub. No.: US 2023/0369413 A1
(43) Pub. Date: Nov. 16, 2023

(54) ELECTRONIC DEVICE MADE OF CARBON SILICIDE AND METHOD OF MANUFACTURING THE SAME

(71) Applicant: Commissariat a I'Energie Atomique et aux Energies Alternatives, Paris (FR)

(72) Inventor: Julie Widiez, Grenoble (FR)

(73) Assignee: Commissariat a I'Energie Atomique et aux Energies Alternatives, Paris (FR)

(21) Appl. No.: 18/357,914

(22) Filed: Jul. 24, 2023

Related U.S. Application Data
(63) Continuation-in-part of application No. 17/534,540, filed on Nov. 24, 2021.

(30) Foreign Application Priority Data
Dec. 17, 2020 (FR) 2013524

(51) Int. Cl. H01L 29/16; H01L 21/02

(52) U.S. Cl. CPC H01L 29/1608; H01L 21/02378; H01L 21/02433

(57) ABSTRACT

An electronic device including a stack of a support substrate made of single-crystal SiC having a first surface and of a layer made of single-crystal SiC including a second surface opposite the first surface. The first surface corresponds to a plane of the SiC single crystal of the support substrate and the second surface corresponds to a plane inclined by at least 1° with respect to a plane in the direction of the SiC single crystal of the layer.

This Application is a Continuation-in-part of U.S. Application Ser. No. 17/534,540, filed Nov. 24, 2021, entitled “ELECTRONIC DEVICE MADE OF CARBON SILICIDE AND METHOD OF MANUFACTURING THE SAME”. Foreign priority benefits are claimed under 35 U.S.C. § 119(a)-(d) or 35 U.S.C. § 365(b) of French application number 2013524, filed Dec. 17, 2020. The entire contents of these applications are incorporated herein by reference in their entirety.

### TECHNICAL BACKGROUND

The present disclosure generally concerns electronic devices made of carbon silicide and their manufacturing methods.

### PRIOR ART

The present disclosure particularly relates to single-crystal substrates or single-crystal carbon silicide (SiC) layers used, for example, for the forming of power electronic components. The SiC crystal comprises many extended defects, particularly basal plane dislocations (BPD), threading edge dislocations (TED), threading screw dislocations (TSD), micropipes (MP), and stacking faults (SF). The defects having the most negative impact on the electric performance of electronic devices using SiC single crystalline substrates are TSDs, MPs, BPDs, and SFs. Single-crystal SiC substrate manufacturers have currently succeeded in decreasing the density of TSDs and of MPs so that these defects no longer have a significant impact on the electric performance of electronic components formed with these substrates. BPD defects are now penalizing.

The manufacturing of a single-crystal SiC substrate having a density of extended defects, and particularly a density of BPDs, smaller than 1,000 defects/cm² has a high cost. To decrease the manufacturing costs of an electronic device using such an SiC substrate, it is known to use a thin single-crystal SiC layer instead of a thick single-crystal SiC substrate, the thin layer being held on a support substrate having a lower manufacturing cost.

In particular, it is known to transfer a thin single-crystal SiC substrate having a low density of defects onto a single-crystal SiC support having a high density of defects, the SiC support advantageously having the same expansion coefficient as the thin SiC layer. However, during subsequent steps of the electronic device manufacturing method, which generally comprise steps having a high thermal budget (anneal and/or epitaxial growth of SiC from the thin layer, the propagation of defects from the support into the rest of the electronic device can be observed, which is not desirable.

### SUMMARY

An embodiment overcomes all or part of the disadvantages of known SiC devices formed from a thin SiC layer transferred onto a low-cost substrate.

According to an embodiment, the electronic device has a low manufacturing cost.

An embodiment provides an electronic device comprising a stack of a support substrate made of single-crystal SiC having a first surface and of a layer made of single-crystal SiC comprising a second surface opposite the first surface. The first surface corresponds to a (0001) plane of the SiC single crystal of the support substrate and the second surface corresponds to a plane inclined by at least 1° with respect to a (0001) plane in the (11-20) direction of the SiC single crystal of the layer.

According to an embodiment, the support substrate has a density of extended defects greater than 1,000 BDP defects/cm².

According to an embodiment, the layer has a density of defects smaller than 250 BPD defects/cm².

According to an embodiment, the second surface is in mechanical contact, also called physical contact, with the first surface.

According to an embodiment, the device comprises at least one electronic component formed at least by treatment of the layer.

An embodiment also provides a method of manufacturing an electronic device comprising the provision of a support substrate made of single-crystal SiC having a first surface, the forming of a layer made of single-crystal SiC attached to the support substrate, the layer comprising a second surface opposite the first surface, the first surface corresponding to a (0001) plane of the SiC single crystal of the support substrate and the second surface corresponding to a plane inclined by at least 1° with respect to a (0001) plane in the (11-20) direction of the SiC single crystal of the layer.

According to an embodiment, the method comprises the forming of said layer from a substrate made of single-crystal SiC.

According to an embodiment, the method comprises the epitaxial growth of single-crystal SiC on said substrate.

According to an embodiment, the method comprises the forming of a fragilized area in the substrate along a plane and the separation of the substrate along said plane into two portions, one of which corresponds to a layer attached to said support substrate.

According to an embodiment, the method comprises the epitaxial growth of single-crystal SiC on said layer.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a partial simplified cross-section view of an embodiment of an electronic device;

FIG. 2A illustrates a step of an embodiment of a method of manufacturing the electronic device of FIG. 1;

FIG. 2B illustrates another step of the method;

FIG. 2C illustrates another step of the method;

FIG. 2D illustrates another step of the method;

FIG. 2E illustrates another step of the method;

FIG. 2F illustrates another step of the method;

FIG. 2G illustrates another step of the method;

FIG. 3A illustrates a step of another embodiment of a method of manufacturing the electronic device of FIG. 1;

FIG. 3B illustrates another step of the method;

FIG. 3C illustrates another step of the method;

FIG. 3D illustrates another step of the method;

FIG. 4A illustrates a step of another embodiment of a method of manufacturing the electronic device of FIG. 1;

FIG. 4B illustrates another step of the method;

FIG. 4C illustrates another step of the method; and

FIG. 4D illustrates another step of the method.

### DESCRIPTION OF THE EMBODIMENTS

Like features have been designated by like references in the various figures. In particular, the structural and/or functional features that are common among the various embodiments may have the same references and may dispose identical structural, dimensional and material properties. For the sake of clarity, only the steps and elements that are useful for an understanding of the embodiments described herein have been illustrated and described in detail. In particular, the steps of manufacturing electronic components on top of and/or inside of a SiC substrate are well known by those skilled in the art and are not described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., it is referred to the orientation of the drawings or to an electronic device in a normal position of use. Unless specified otherwise, the expressions “around”, “approximately”, “substantially” and “in the order of” signify within 10%, and preferably within 5%. Unless specified otherwise, the expressions “around”, “approximately”, “substantially” and “in the order of” signify within 10%, and preferably within 5%.

In the following description, the density of defects of a SiC single crystal designates the density of BPD defects.

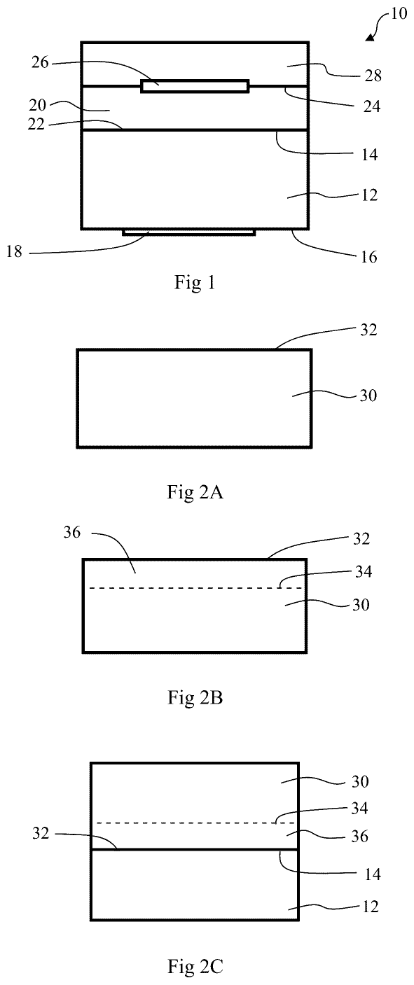

FIG. 1 is a partial simplified cross-section view of an electronic device 10.

Electronic device 10 comprises:
a support substrate 12 made of single-crystal SiC with a first density of defects, having an upper surface 14 and a lower surface 16, opposite to upper surface 14;
optionally at least one metal track 18 in contact with the lower surface 16 of support substrate 12;
a layer 20 made of single-crystal SiC with a second density of defects smaller than the first density of defects, layer 20 having a lower surface 22 resting on surface 14 and in contact with support substrate 12, and an upper surface 24 on the side opposite to support substrate 12; and
an interconnection and/or coating structure 28 covering layer 20 on the side of surface 24.

Electronic device 10 may optionally comprise at least one electronic component, very schematically shown by an area 26 of square shape in FIG. 1. Electronic component 26 may be formed in layer 20 and/or on top of layer 20. Electronic component 26 may extend across the entire thickness of layer 20 and/or across the entire thickness of support substrate 12, particularly in the case of a power electronic component.

According to a variant, electronic device 10 may comprise a support, not shown, having support substrate 12 attached thereon, on the side of lower surface 16.

Support substrate 12 is made of single-crystal SiC. According to an embodiment, support substrate 12 is of the 4H polytype, which exhibits a hexagonal crystal system. As a variant, support substrate 12 is of the 6H polytype, or of another polytype. The BPD density of support substrate 12 is greater than 1,000 defects/cm², preferably greater than 1,500 defects/cm², more preferably greater than 3,000 defects/cm². According to an embodiment, surfaces 14 and 16 are substantially planar. Preferably, surfaces 14 and 16 are parallel. Upper surface 14 corresponds to a basal plane of the crystal, that is, to a (0001) crystallographic plane. The thickness of support substrate 12 is in the range from 300 μm to 1,000 μm, before a possible thinning step. After a thinning step, the thickness of support substrate 12 may be decreased to typically 150 μm. Support substrate 12 may be doped.

Layer 20 is made of single-crystal SiC. The BPD density of layer 20 is smaller than 1,000 defects/cm², preferably smaller than 500 defects/cm², more preferably smaller than 250 defects/cm², more preferably still smaller than 100 defects/cm². According to an embodiment, surface 22 is substantially planar. According to an embodiment, surface 24 is substantially planar. According to an embodiment, surfaces 22 and 24 are parallel. Upper surface 24 corresponds to a plane forming an angle, with respect to a (0001) plane in the (11-20) direction of the crystal, between 1° and 10°, preferably between 2° and 8°, in particular equal to approximately 4°. The thickness of layer 20 is in the range from 100 nm to 15 μm.

Layer 20 may be doped. The dopant concentration in layer 20 may be non-homogeneous. According to an embodiment, layer 20 may comprise a stack of at least first and second sub-layers of single-crystal SiC, coupled together by an epitaxial relation, with different dopant concentrations.

According to an embodiment, layer 20 may comprise a homogeneous BPD density. As a variant, layer 20 may comprise a stack of at least first and second sub-layers of single-crystal SiC, coupled together by an epitaxial relation, the first sub-layer being located on the side of support substrate 12, the BPD density of the second sub-layer being smaller than the BPD density of the first sub-layer. The BPD density of the first sub-layer may be in the range from 100 defects/cm² to 500 defects/cm², and the BPD density of second sub-layer 38 may be smaller than 50 defects/cm².

Electronic component 26 may be intended for a microwave frequency, high-temperature, and/or high-voltage operation. As an example, it may correspond to a Schottky diode, a JFET transistor, a MOSFET transistor, a bipolar transistor, or a thyristor. Electronic component 26 may be formed by processing layer 20 and possibly support substrate 12.

Structure 28 may correspond to an insulating layer. As a variant, it may comprise a stack of insulating layers having conductive tracks and conductive vias extending therebetween and therethrough.

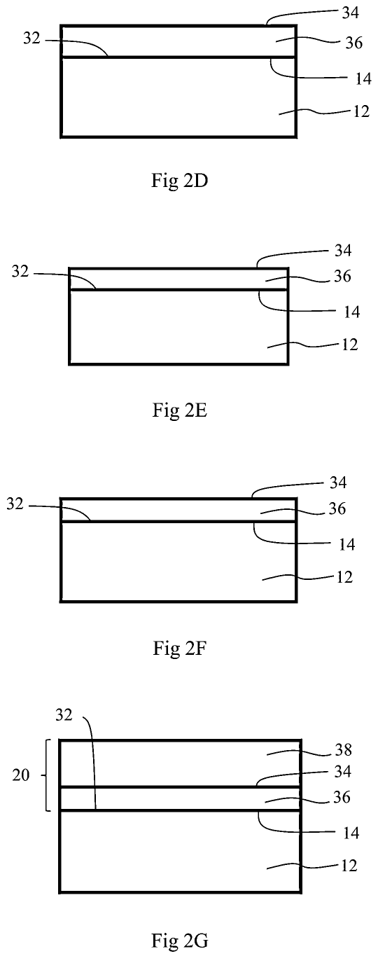

FIGS. 2A to 2G are partial simplified cross-section views of structures obtained at successive steps of another embodiment of a method of manufacturing the electronic device 10 shown in FIG. 1.

FIG. 2A shows a single-crystal SiC substrate 30 having an upper surface 32. The BPD density of substrate 30 is smaller than 1,000 defects/cm², preferably smaller than 500 defects/cm², more preferably smaller than 250 or even 100 defects/cm². Upper surface 32 substantially corresponds to a plan which exhibits a cutting angle. The cutting angle is defined as the angle between the mean free surface of the single crystal and a dense crystallographic plane of the single crystal. In the case of hexagonal SiC, the dense crystallographic plane is the (0001) plane. Upper surface 32 has a cutting angle with respect to the (0001) plane in the (11-20) direction in the range from 1° to 10°, preferably from 2° to 8°, in particular equal to approximately 4°.

FIG. 2B shows the structure obtained after a step of ion implantation on the side of upper surface 32, which results in the forming of a substantially planar fragilized buried area 34 in substrate 30, delimiting with upper surface 32 a thin layer 36 which will be transferred as described in further detail hereafter. Layer 36 is intended to form part of the previously-described layer 20, as described in further detail hereafter. The transfer method known as “Smart Cut™” is widely known in literature. The ion implantation step may be a step of implantation of light-mass species, for example, of hydrogen, helium, or a combination of these two species. The adjustment of the implantation energy enables to vary the implantation depth, that is, the distance between plane 34 and upper surface 32. The implantation energies may be in the range from 40 keV to 200 keV. The doses used may be in the range from 10¹⁶/cm² to 10¹⁷/cm². The ion implantation may be carried out at a temperature lower than 500° C., particularly at ambient temperature. Plane 34 is substantially parallel to surface 32 and thus exhibits an angle with respect to the (0001) plane in the (11-20) direction of the SiC crystal in the range from 1° to 10°, preferably from 2° to 8°, in particular equal to approximately 4°. Alternately, layer 20 may be formed from other known thin film transfer techniques.

FIG. 2C shows the structure obtained after a step of assembly of substrate 30 on support substrate 12, and more precisely of the surface 32 of substrate 30 to the surface 14 of support substrate 12. According to an embodiment, the bonding of substrate 30 to support substrate 12 is a direct bonding, that is, with no addition of a bonding material between substrate 30 and support substrate 12. It may comprise the forming of a layer on the surface 32 of substrate 30, and/or on the surface 14 of support substrate 12 to ease the assembly of substrate 30 with support substrate 12, where this layer may be a metal layer, for example, made of tungsten (W), a semiconductor layer, for example, made of silicon (SiC) or of amorphous SiC. The step of bonding by direct bonding comprises placing into contact the surface 32 of substrate 30 against the surface 14 of support substrate 12, which causes the molecular bonding of substrate 30 to support substrate 12. This bonding may be performed in an ambient atmosphere, or under a controlled atmosphere and in particular under high vacuum, in the order of 10⁻⁶ Pa or less. It may be carried out at an ambient temperature or at higher temperature, assisted or not by a compression. A thermal anneal is generally carried out to strengthen the bonding.

FIG. 2D shows the structure after a step of separation of substrate 30 at the level of fragile buried plane 34 into two portions, layer 36 remaining attached to support substrate 12. According to an embodiment, the thickness of layer 36 is for example in the range from 100 nm to 1.5 μm. The separation step may comprise a sufficient energy input to separate substrate 30 into two portions at the level of plane 34. The energy input may comprise a thermal energy input, for example, by an anneal or a laser scanning, or a mechanical energy input or also a combination of thermal and mechanical stress.

The obtained structure thus comprises a single-crystal SiC layer 36 comprising a low density of BPDs (smaller than 1,000 defects/cm², preferably smaller than 500 defects/cm², more preferably smaller than 100 defects/cm²), on a low-cost support substrate 12 comprising a higher density of BPDs (greater than 1,000 defects/cm², and preferably greater than 1,500 or even 3,000 defects/cm²). Advantageously, during thermal treatments (during the bonding strengthening anneal and/or the step of separation of substrate 30), the BPDs of support substrate 12 have been blocked in the basal plane of surface 14 and have not emerged into layer 36, which thus remains of very good quality.

The exposed surface of layer 36 which substantially corresponds to plane 34 exhibits a cutting angle with respect to the (0001) plane in the (11-20) direction of the SiC crystal in the range from 1° to 10°, preferably from 2° to 8°, in particular equal to approximately 4°.

FIG. 2E shows the structure obtained after steps of cleaning, polishing, smoothing, or etching of the surface 34 of layer 36. This may cause a thinning of layer 36, the free surface 34 obtained after this step of polishing always exhibiting a cutting angle with respect to the (0001) plane in the (11-20) direction of the SiC crystal in the range from 1° to 10°, preferably from 2° to 8°, in particular equal to approximately 4°.

FIG. 2F for example shows the structure obtained after a step of thermal anneal, for example, at a temperature greater than 1,500° C., for example, at approximately 1,700° C., for a duration longer than 10 minutes, for example, for approximately 30 minutes. Advantageously, during the anneal, the BPDs of support substrate 12 are blocked in the basal plane of surface 14 and do not emerge into layer 36. The steps previously described in relation with FIGS. 2E and 2F enable to substantially remove all the defects induced during the ion implantation.

FIG. 2G shows the structure obtained after a step of growth of a single-crystal SiC layer 38 by epitaxy on layer 36 from surface 34. Layer 38 may have a doping different from that of layer 36. It may have a density of defects smaller than the density of defects of layer 36. This step enables to form layer 38 with a BPD density smaller, in the order of from 10 times to 100 times smaller, than the BPD density of layer 36. This is due to the fact that BPDs are transformed into TEDs during the epitaxy step by adequate control of the growth parameters during the epitaxy step, particularly the growth speed or also the C/S ratio. TEDs are defects which do not or only slightly impact electric devices, conversely to BPDs. Epitaxial SiC layer 38 may comprise a BPD density smaller than 50 defects/cm². The assembly of layers 36 and 38 then forms the SiC layer 20 previously-described in relation with FIG. 1. This layer 20 advantageously has a thickness greater than 3 μm, typically in the order of from 5 to 15 μm, or even more to enable, in particular, the forming of power components. The upper surface 24 of layer 36 having an angle with respect to the (0001) plane in the (11-20) direction of the SiC crystal between 1° and 10°, preferably between 2° and 8°, in particular equal to approximately 4°, the epitaxial growth of layer 38 may be carried out by methods compatible with an industrial exploitation. Indeed, the epitaxial growth on a free surface of the SiC crystal exhibiting an angle with respect to the (0001) plane in the (11-20) direction of the SiC crystal smaller than 1° may hardly be achieved by methods compatible with an industrial exploitation. Advantageously, during the epitaxy performed at high temperature, the BPDs of support substrate 12 are blocked in the basal plane of surface 14 and do not emerge into layer 20, which thus remains of very good quality.

As a variant, layer 38 is not present. Layer 36 then corresponds to the layer 20 previously described in relation with FIG. 1. It may be directly processed to form components.

The method may comprise subsequent steps of forming of electronic components, particularly at the level of layer 20, and materialized in FIG. 1 by area 26, and of forming of the interconnection/coating structure 28 previously described in relation with FIG. 1. Advantageously, during these subsequent steps, the BPDs of support substrate 12 are also blocked in the (0001) plane of surface 14 and do not emerge through layer 20.

These subsequent steps may further comprise the thinning of support substrate 12, for example, by polishing, grinding, and/or chemical etching. These subsequent steps may comprise the forming of metal tracks 18. As an example, a plurality of copies of electronic device 10 may be formed inside and on top of layer 20. A step of separation of the electronic devices, for example, by sawing, can then be provided.

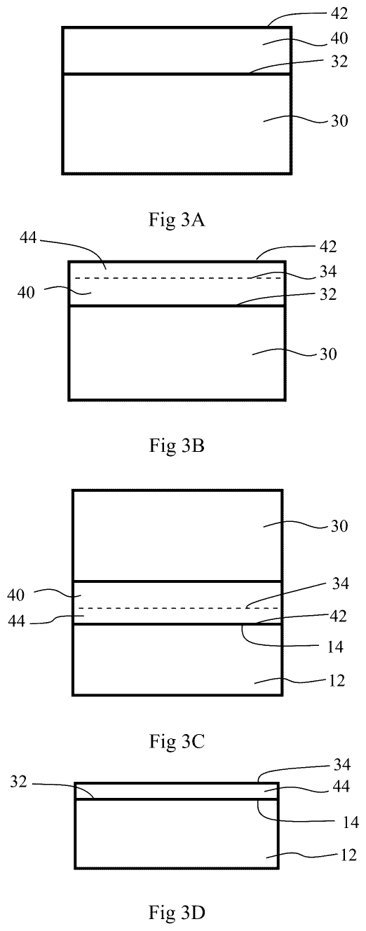

FIGS. 3A to 3D are partial simplified cross-section views of structures obtained at successive steps of another embodiment of a method of manufacturing the electronic device 10 shown in FIG. 1.

FIG. 3A shows the structure obtained after a step of growth of a SiC layer 40 by epitaxy on the SiC substrate 30 from surface 32. As previously described, substrate 30 has a good crystalline quality with few defects, the BPD density of substrate 30 being smaller than 1,000 defects/cm², preferably smaller than 500 defects/cm², more preferably smaller than 250 or even 100 defects/cm². Layer 40 may have the same doping or a different doping of SiC substrate 30. This step enables to form layer 40 with a BPD density smaller, preferably 10 times smaller, more preferably 100 times smaller, than the BPD density of substrate 30. This is due to the fact that BPDs are transformed into TEDs during the epitaxy step by adequate control of the growth parameters during the epitaxy step, particularly the growth speed or also ratio C/S. TEDs are defects which do not or only slightly impact electric devices, conversely to BPDs. Layer 40 has a free surface 42.

FIG. 3B shows the structure obtained after an implantation step which results in the forming of a fragile buried plane 34 in layer 40, delimiting, with the free surface 42 of layer 40, a thin layer 44 intended to be transferred as described in detail hereafter. The implantation step may be implemented as previously described in relation with FIG. 2B.

FIG. 3C shows the structure obtained after a step of bonding of layer 40 to support substrate 12, and more precisely the surface 42 of layer 40 to the surface 14 of support substrate 12. The bonding step may be implemented as previously described in relation with FIG. 2C.

FIG. 3D shows the structure after a step of separation of layer 40 at the level of fragile buried plane 34 into two portions, layer 44 remaining attached to support substrate 12. The separation step may be implemented as previously described in relation with FIG. 2D.

The obtained structure thus comprises a single-crystal SiC layer 44 comprising a light density of BPDs (smaller than 500 defects/cm², preferably smaller than 250 defects/cm², more preferably smaller than 100 defects/cm²) on a low-cost support substrate 12 comprising a stronger density of BPDs. The exposed surface of layer 44 which substantially corresponds to plane 34 exhibits a cutting angle with respect to the basal SiC plane in the range from 1° to 10°, preferably from 2° to 8°, in particular equal to approximately 4°.

The subsequent steps of the method may correspond to what has been previously described in relation with FIGS. 2E to 2G.

If a layer is epitaxially grown on the transferred layer 44, the BPD density in this layer will be further decreased, by a factor in the order of from 10 to 100 with respect to layer 44. A BPD density smaller than 50 defects/cm², preferably smaller than 20 defects/cm², more preferably smaller than 10 defects/cm², is thus obtained.

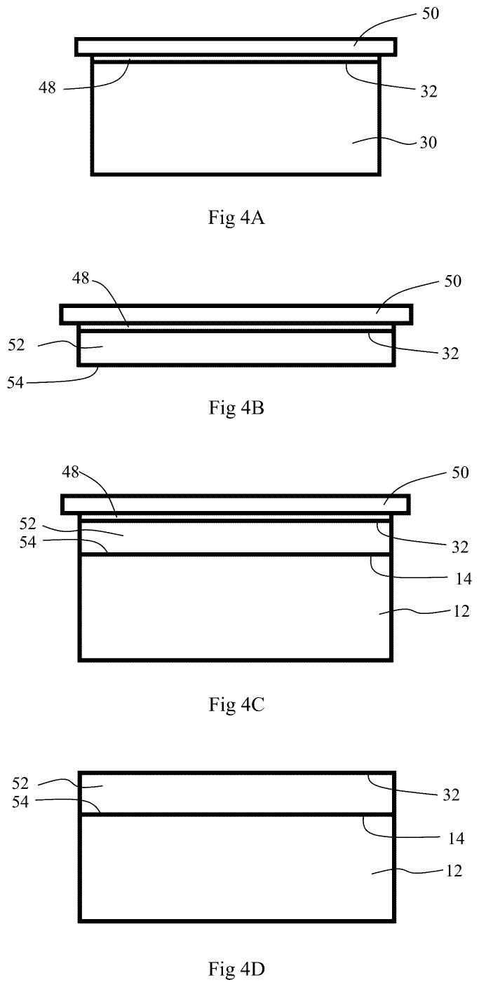

FIGS. 4A to 4D are partial simplified cross-section views of structures obtained at successive steps of another embodiment of a method of manufacturing the electronic device 10 shown in FIG. 1 for which the sampling of the single-crystal film is performed by a spalling technique.

FIG. 4A shows the structure obtained after a step of deposition of a highly stressed layer 48, for example, made of nitride on the upper surface 32 of substrate 30 and a step of application of an adhesive strip 50 to the surface of stressed layer 48.

FIG. 4B shows the structure obtained after a step of separation by spalling of a layer 52 of substrate 30 forming one piece with stressed layer 48, which remained attached to adhesive strip 50. Layer 52 has a free surface 54 on the side opposite to adhesive strip 50. The thickness of layer 52 may be in the range from 100 nm to 1.5 μm.

FIG. 4C shows the structure obtained after a step of adhesion of layer 52 to support substrate 12, and more precisely of the surface 54 of layer 52 to the surface 14 of support substrate 12. The bonding step may be implemented as previously described in relation with FIG. 2C after an adapted surface treatment of surface 54, and particularly a chemical-mechanical polishing, to make it compatible with this bonding. Indeed, surface 54 is very rough after the spalling.

FIG. 4D shows the structure obtained after the removal of adhesive strip 50 and then the removal of stressed layer 48, for example, by a selective etching.

The subsequent steps of the method may correspond to what has been previously described in relation with FIGS. 2E to 2G.

Various embodiments and variants have been described. Those skilled in the art will understand that certain features of these various embodiments and variants may be combined, and other variants will occur to those skilled in the art. In particular, the embodiment described in relation with FIGS. 3A to 3D may be implemented with the embodiment described in relation with FIGS. 4A to 4D.

Finally, the practical implementation of the described embodiments and variations is within the abilities of those skilled in the art based on the functional indications given hereabove.

1. Electronic device comprising a stack of a support substrate made of single-crystal SiC having a first surface and of a layer made of single-crystal SiC comprising a second surface opposite the first surface, wherein the first surface corresponds to a plane of the SiC single crystal of the support substrate and the second surface corresponds to a plane inclined by at least 1° with respect to a plane in the direction of the SiC single crystal of the layer.

2. Electronic device according to claim 1, wherein the support substrate has a density of extended defects greater than 1,000 BPD defects/cm².

3. Electronic device according to claim 1, wherein the layer has a density of defects smaller than 250 BPD defects/cm².

4. Electronic device according to claim 1, wherein the second surface is in mechanical contact with the first surface.

5. Electronic device according to claim 1, comprising at least one electronic component formed at least by treatment of the layer.

6. Method of manufacturing an electronic device comprising the provision of a support substrate made of single-crystal SiC having a first surface, the forming of a layer made of single-crystal SiC attached to the support substrate, the layer comprising a second surface opposite the first surface, wherein the first surface corresponds to a plane of the SiC single crystal of the support substrate and the second surface corresponds to a plane inclined by at least 1° with respect to a plane in the direction of the SiC single crystal of the layer.

7. Method according to claim 6, comprising the forming of said layer from a substrate made of single-crystal SiC.

8. Method according to claim 7, comprising the epitaxial growth of single-crystal SiC on said substrate.

9. Method according to claim 7, comprising the forming of a fragilized area in the substrate along a plane and the separation of the substrate along said plane into two portions, one of which corresponds to a layer attached to said support substrate.

10. Method according to claim 6, comprising the epitaxial growth of single-crystal SiC on said layer.
